(19) United States
(12) Patent Application Publication
(10) Pub. No.: US 2017/0250348 A1
(43) Pub. Date: Aug. 31, 2017

(54) ORGANIC LIGHT EMITTING DEVICE

(71) Applicant: SAMSUNG DISPLAY CO., LTD., Yongin-si (KR)

(72) Inventors: Hyundo JIN, Yongin-si (KR); Jaeyoung LEE, Yongin-si (KR); Youngtak LEE, Suwon-si (KR)

(21) Appl. No.: 15/241,236

(22) Filed: Aug. 19, 2016

(30) Foreign Application Priority Data
Feb. 25, 2016 (KR) 10-2016-0022396

(51) Int. Cl. H01L 51/00

(52) U.S. Cl. CPC H01L 51/0067; H01L 51/0073; H01L 51/0072; H01L 51/52

(57) ABSTRACT

An organic light emitting device including a first electrode; a hole transport region on the first electrode; an emission layer on the hole transport region; a first buffer layer on the emission layer; a second buffer layer on the first buffer layer; an electron transport region on the second buffer layer; and a second electrode on the electron transport region, wherein the first buffer layer includes a first buffer compound represented by the following Formula 1 or Formula 2, and the second buffer layer includes a second buffer compound represented by the following Formula 3:

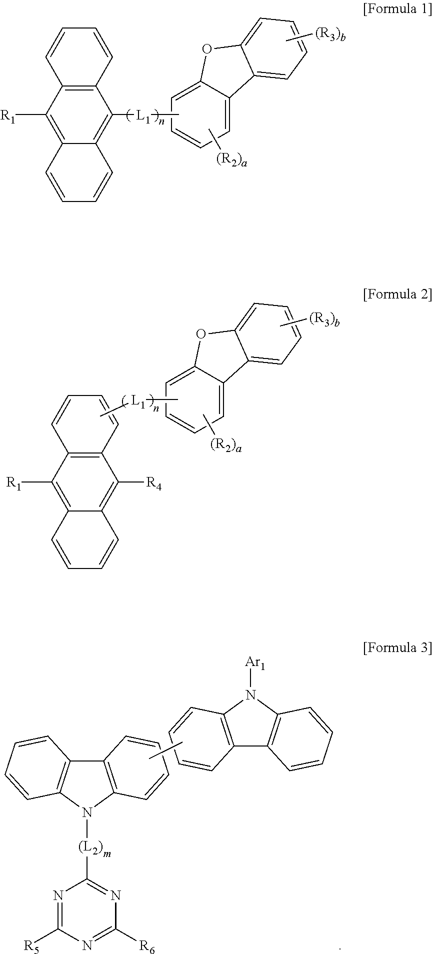

### CROSS-REFERENCE TO RELATED APPLICATION

Korean Patent Application No. 10-2016-0022396, filed on Feb. 25, 2016, in the Korean Intellectual Property Office, and entitled: “Organic Light Emitting Device,” is incorporated by reference herein in its entirety.

### BACKGROUND

1. Field

Embodiments relate to an organic light emitting device.

2. Description of the Related Art

Recently, the development of an organic light emitting display device as an image display device is being actively conducted. Different from a liquid crystal display device, the organic light emitting display device is a self-luminescent display device in which holes and electrons injected from a first electrode and a second electrode recombine in an emission layer, and a luminescent material including an organic compound in the emission layer emits light to attain display.

As an organic light emitting device, an organic device may include, e.g., a first electrode, a hole transport region disposed on the first electrode, an emission layer disposed on the hole transport region, an electron transport region disposed on the emission layer, and a second electrode disposed on the electron transport region. Holes are injected from the first electrode, and the injected holes move and are injected to the emission layer. Meanwhile, electrons are injected from the second electrode, and the injected electrons move and are injected to the emission layer. The holes and electrons injected to the emission layer recombine to generate excitons in the emission layer. The organic light emitting device emits light using light generated by the radiation deactivation of the excitons. In addition, the organic light emitting device is not limited to the above-described configuration, and various modifications may be possible.

### SUMMARY

Embodiments are directed to an organic light emitting device.

The embodiments may be provided by realizing an organic light emitting device, including a first electrode; a hole transport region on the first electrode; an emission layer on the hole transport region; a first buffer layer on the emission layer; a second buffer layer on the first buffer layer; an electron transport region on the second buffer layer; and a second electrode on the electron transport region, wherein the first buffer layer includes a first buffer compound represented by the following Formula 1 or Formula 2, and the second buffer layer includes a second buffer compound represented by the following Formula 3:

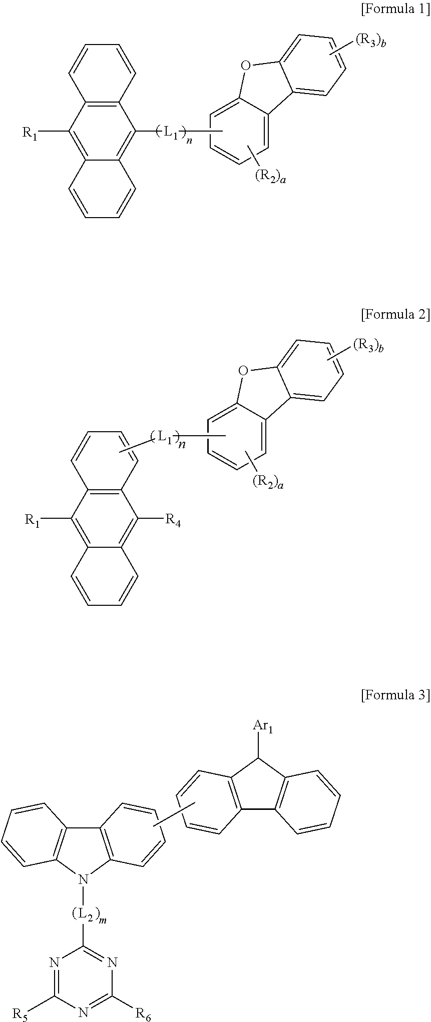

wherein, in Formulae 1 to 3, R₁, R₂, R₃, R₄, R₅ and R₆ are each independently a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms, R₁, R₂, R₃, R₄, R₅ and R₆ are separate or adjacent ones thereof combine to form a ring, Ar₁ is a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms, L₁ and L₂ are each independently a direct linkage, a substituted or unsubstituted arylene group having 6 to 30 ring carbon atoms, or a substituted or unsubstituted heteroarylene group having 4 to 30 ring carbon atoms, a is an integer of 0 to 3, b is an integer of 0 to 4, and n and m are each independently 0 or 1.

In Formulae 1 and 2, R₁ may be a substituted or unsubstituted phenyl group or a substituted or unsubstituted naphthyl group.

In Formulae 1 and 2, L₁ may be a substituted or unsubstituted m-phenylene group, substituted or unsubstituted p-phenylene group, a substituted or unsubstituted fluorenylene group, or a substituted or unsubstituted dibenzofuranyl group.

In Formulae 1 and 2, a may be 2 or 3 and adjacent ones of R₂ may combine to form a ring.

In Formulae 1 and 2, b may be 2, 3, or 4, and adjacent one of R₃ may combine to form a ring.

In Formula 2, R₄ may be a substituted or unsubstituted phenyl group.

The first buffer compound may include one of the following Compounds 1 to 9:

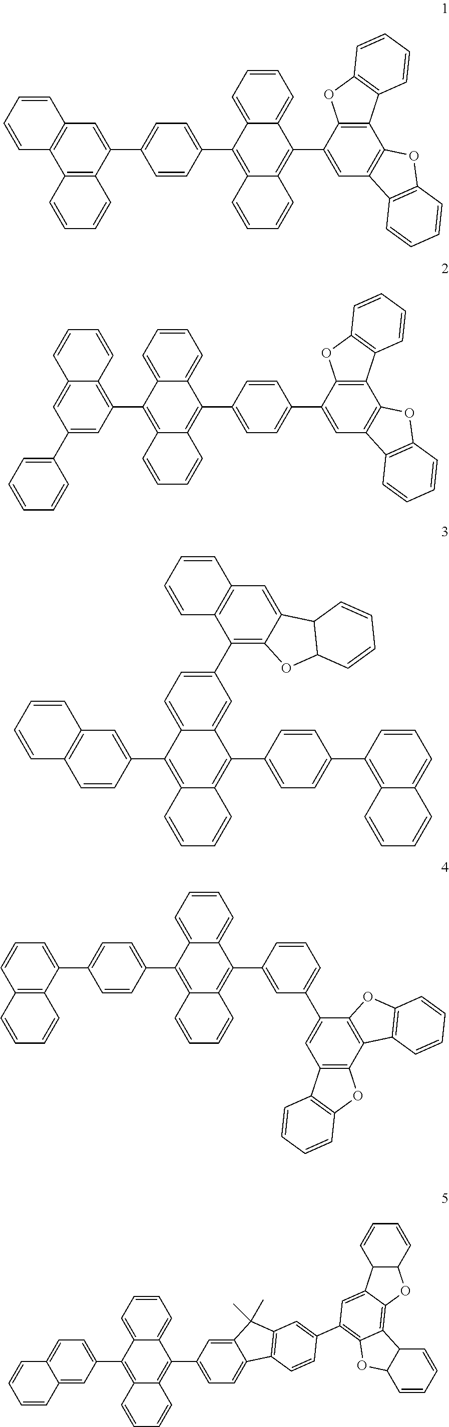 [SMILES: c1ccc2c(c1)cc(-c1ccc(-c3c4ccccc4c(-c4cc5c6ccccc6oc5c5c4oc4ccccc45)c4ccccc34)cc1)c1ccccc12 ; c1ccc(-c2cc(-c3c4ccccc4c(-c4ccc(-c5cc6c7ccccc7oc6c6c5oc5ccccc56)cc4)c4ccccc34)c3ccccc3c2)cc1 ; C1=CC2Oc3c(cc4ccccc4c3-c3ccc4c(-c5ccc6ccccc6c5)c5ccccc5c(-c5ccc(-c6cccc7ccccc67)cc5)c4c3)C2C=C1 ; c1cc(-c2c3ccccc3c(-c3ccc(-c4cccc5ccccc45)cc3)c3ccccc23)cc(-c2cc3c4ccccc4oc3c3c2oc2ccccc23)c1 ; CC1(C)c2cc(-c3cc4c(c5c3OC3C=CC=CC53)OC3C=CC=CC43)ccc2-c2ccc(-c3c4ccccc4c(-c4ccc5ccccc5c4)c4ccccc34)cc21]

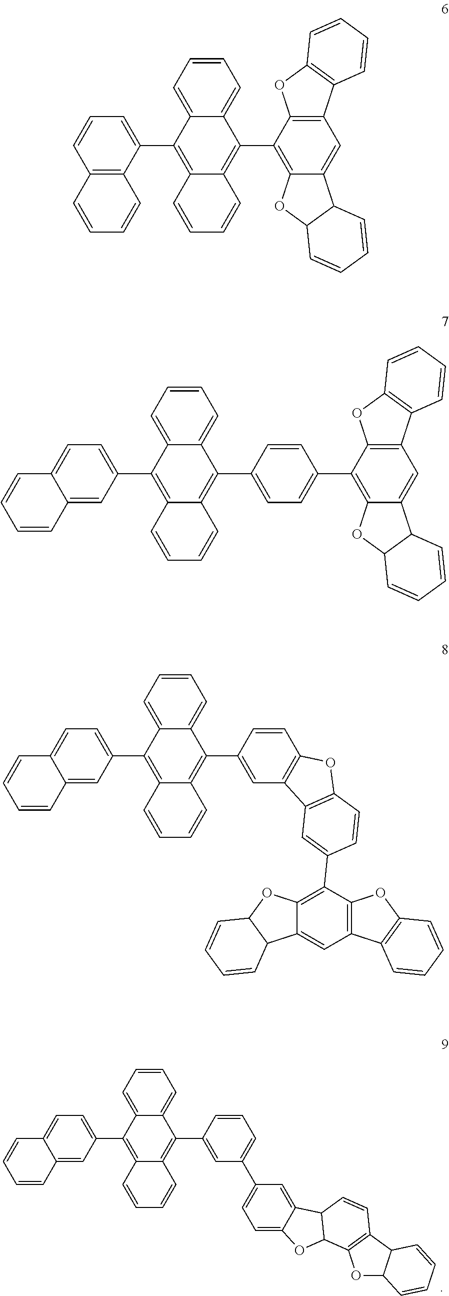 [SMILES: C1=CC2Oc3c(cc4c(oc5ccccc54)c3-c3c4ccccc4c(-c4cccc5ccccc45)c4ccccc34)C2C=C1 ; C1=CC2Oc3c(cc4c(oc5ccccc54)c3-c3ccc(-c4c5ccccc5c(-c5ccc6ccccc6c5)c5ccccc45)cc3)C2C=C1 ; C1=CC2Oc3c(cc4c(oc5ccccc54)c3-c3ccc4oc5ccc(-c6c7ccccc7c(-c7ccc8ccccc8c7)c7ccccc67)cc5c4c3)C2C=C1 ; C1=CC2OC3=C(C=CC4c5cc(-c6cccc(-c7c8ccccc8c(-c8ccc9ccccc9c8)c8ccccc78)c6)ccc5OC34)C2C=C1]

The second buffer compound may be represented by the following Formula 4:

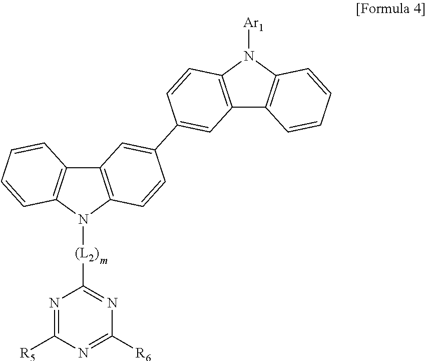

wherein, in Formula 4, Ar₁, L₂, m, R₅ and R₆ may be defined the same as those of Formula 3.

In Formula 3, Ar₁ may be a substituted or unsubstituted phenyl group.

In Formula 3, L₂ may be a substituted or unsubstituted m-phenylene group or a substituted or unsubstituted p-phenylene group.

In Formula 3, R₅ and R₆ may each independently be selected from a substituted or unsubstituted phenyl group, a substituted or unsubstituted biphenyl group, a substituted or unsubstituted naphthyl group, or a substituted or unsubstituted pyridine group.

The second buffer compound may include one of the following Compounds 1′ to 10′:

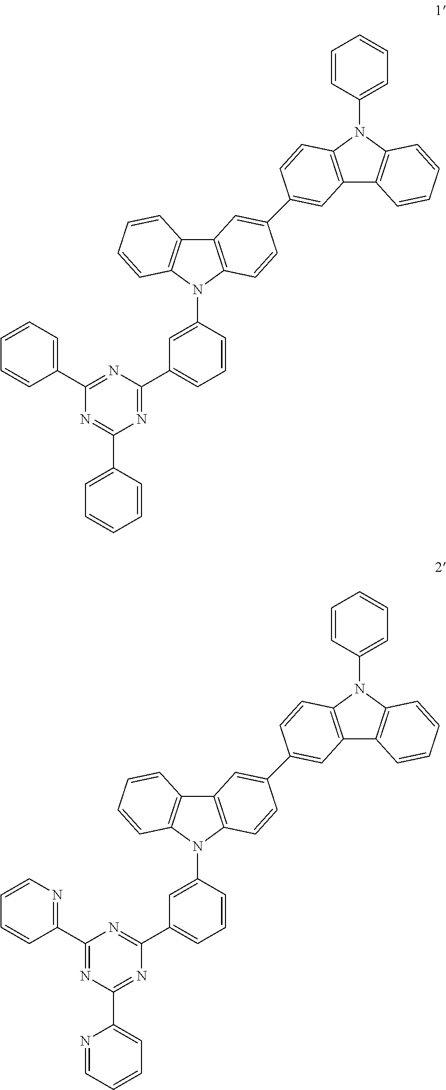 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-n2c3ccccc3c3cc(-c4ccc5c(c4)c4ccccc4n5-c4cccc(-c5nc(-c6ccccn6)nc(-c6ccccn6)n5)c4)ccc32)cc1]

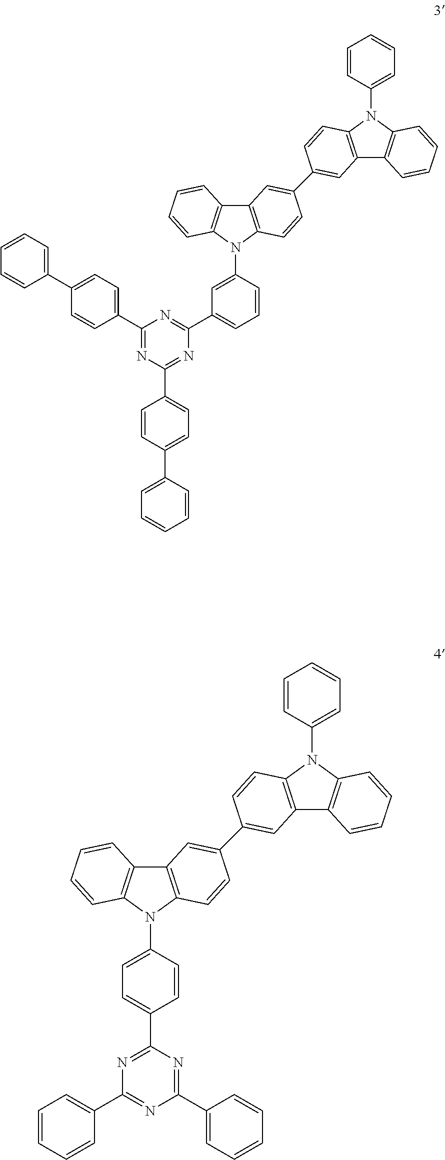 [SMILES: c1ccc(-c2ccc(-c3nc(-c4ccc(-c5ccccc5)cc4)nc(-c4cccc(-n5c6ccccc6c6cc(-c7ccc8c(c7)c7ccccc7n8-c7ccccc7)ccc65)c4)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

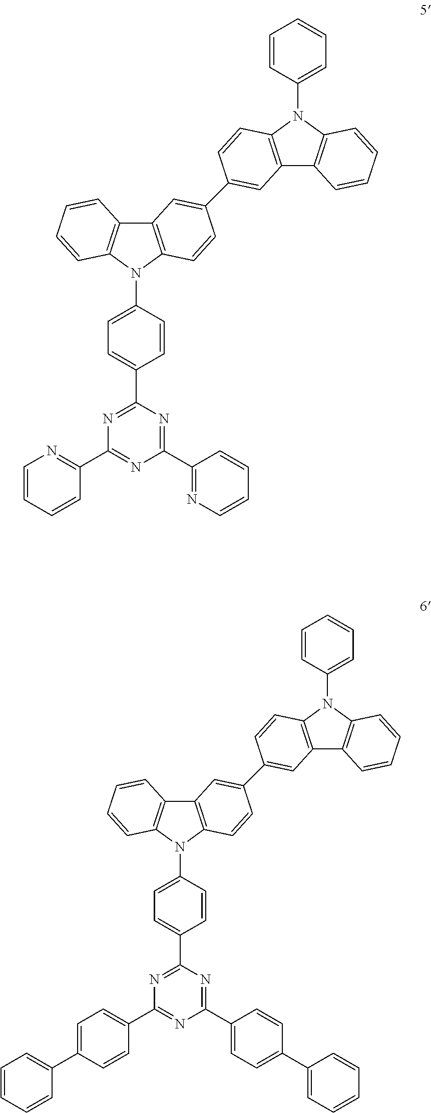 [SMILES: c1ccc(-n2c3ccccc3c3cc(-c4ccc5c(c4)c4ccccc4n5-c4ccc(-c5nc(-c6ccccn6)nc(-c6ccccn6)n5)cc4)ccc32)cc1 ; c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1]

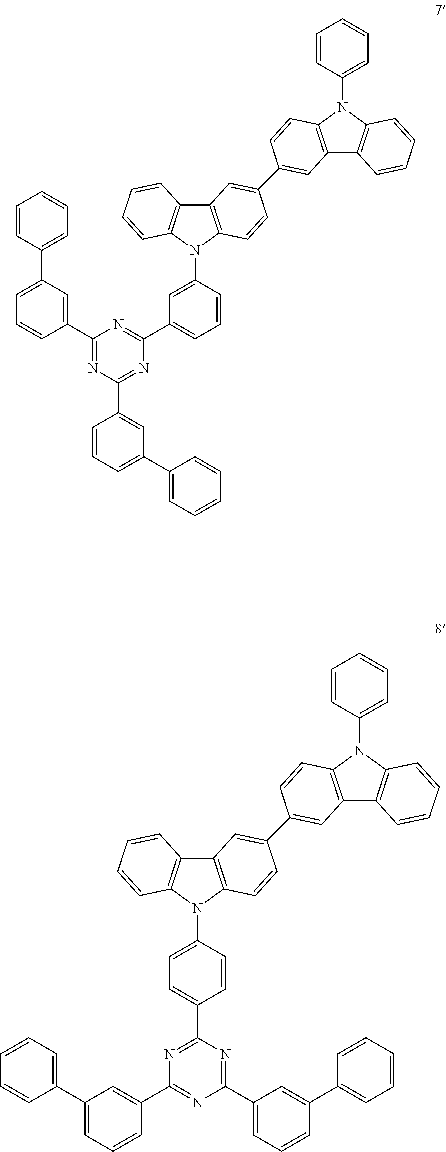 [SMILES: c1ccc(-c2cccc(-c3nc(-c4cccc(-c5ccccc5)c4)nc(-c4cccc(-n5c6ccccc6c6cc(-c7ccc8c(c7)c7ccccc7n8-c7ccccc7)ccc65)c4)n3)c2)cc1 ; c1ccc(-c2cccc(-c3nc(-c4ccc(-n5c6ccccc6c6cc(-c7ccc8c(c7)c7ccccc7n8-c7ccccc7)ccc65)cc4)nc(-c4cccc(-c5ccccc5)c4)n3)c2)cc1]

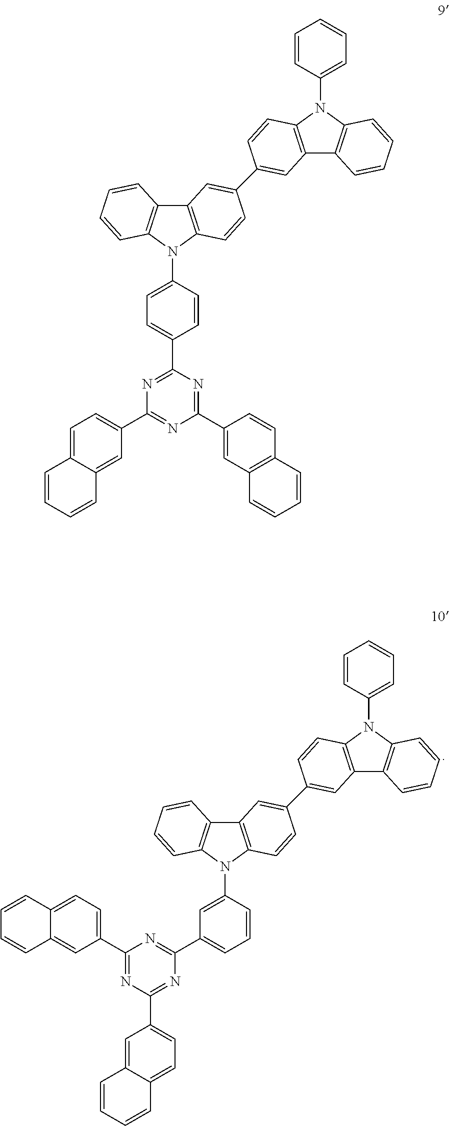 [SMILES: c1ccc(-n2c3ccccc3c3cc(-c4ccc5c(c4)c4ccccc4n5-c4ccc(-c5nc(-c6ccc7ccccc7c6)nc(-c6ccc7ccccc7c6)n5)cc4)ccc32)cc1 ; c1ccc(-n2c3ccccc3c3cc(-c4ccc5c(c4)c4ccccc4n5-c4cccc(-c5nc(-c6ccc7ccccc7c6)nc(-c6ccc7ccccc7c6)n5)c4)ccc32)cc1]

The hole transport region may include a hole injection layer; and a hole transport layer on the hole injection layer.

The electron transport region may include an electron transport layer; and an electron injection layer on the electron transport layer.

### BRIEF DESCRIPTION OF THE DRAWINGS

Features will be apparent to those of skill in the art by describing in detail exemplary embodiments with reference to the attached drawings in which:

FIG. 1 illustrates a cross-sectional view schematically showing an organic light emitting device according to an embodiment;

FIG. 2 illustrates a cross-sectional view schematically showing an organic light emitting device according to an embodiment;

FIG. 3A illustrates a graph showing current efficiency relative to grey level for Comparative Example 1 and Example 1;

FIG. 3B illustrates a graph showing current efficiency relative to grey level for Comparative Example 1; and

FIG. 3C illustrates a graph showing current efficiency relative to grey level for Example 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, etc. may be used herein to describe various elements, these elements should not be limited by these terms. These terms are only used to distinguish one element from another element. Thus, a first element could be termed a second element without departing from the teachings herein. Similarly, a second element could be termed a first element. As used herein, the singular forms are intended to include the plural forms as well, unless the context clearly indicates otherwise.

It will be further understood that the terms “comprises”, “includes”, “including”, and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, the term “substituted or unsubstituted” corresponds to substituted or unsubstituted with at least one substituent selected from the group of deuterium, a halogen group, a nitrile group, a nitro group, an amino group, a silyl group, a boron group, a phosphine oxide group, an alkyl group, an alkoxy group, an alkenyl group, a fluorenyl group, an aryl group, and a heterocyclic group. In addition, each of the substituents may be substituted or unsubstituted. For example, the biphenyl group may be interpreted as an aryl group or a phenyl group substituted with a phenyl group.

In the description, the terms “forming a ring via the combination of adjacent groups” or “combine to form a ring” may mean forming a substituted or unsubstituted hydrocarbon ring, or substituted or unsubstituted heterocycle via the combination of adjacent groups. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In addition, the ring formed via the combination of adjacent groups may be combined with another ring to form, e.g., a spiro structure.

In the description, the term “an adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other.

In the description, the halogen may include fluorine, chlorine, bromine, and/or iodine.

In the description, the alkyl may be a linear, branched, or cyclic type. The carbon number of the alkyl may be from 1 to 30, from 1 to 20, from 1 to 10, or from 1 to 6. The alkyl may include, e.g., methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, c-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc.

In the description, the aryl group means an optional functional group or substituent derived from an aromatic hydrocarbon ring. The aryl group may be a monocyclic aryl group or a polycyclic aryl group. The carbon number for forming a ring in the aryl group may be 6 to 30, or 6 to 20. Examples of the aryl group may include phenyl, naphthyl, fluorenyl, anthracenyl, phenanthryl, biphenyl, terphenyl, quaterphenyl, quinqphenyl, sexiphenyl, triphenylene, pyrenyl, benzofluoranthenyl, chrysenyl, etc.

In the description, the fluorenyl group may be substituted, and two substituents may combine to each other to form a spiro structure.

In the description, the heteroaryl may be a heteroaryl including at least one of O, N, or S as a heteroatom. The carbon number for forming a ring of the heteroaryl may be 2 to 30, or 2 to 20. Examples of the heteroaryl may include thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phenoxazyl, phthalazinyl, pyrido pyrimidinyl, pyrido pyrazinyl, pyrazino pyrazinyl, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuranyl, phenanthroline, thiazolyl, isooxazolyl, oxadiazolyl, thiadiazolyl, benzothiazolyl, phenothiazinyl, dibenzufuranyl, etc.

In the description, the explanation with respect to the aryl groups may be applied to the arylene groups, except an arylene is a divalent group.

In the description, the silyl may include alkyl silyl and aryl silyl. Examples of the silyl may include trimethylsilyl, triethylsilyl, t-butyldimethylsilyl, vinyldimethylsilyl, propyldimethylsilyl, triphenylsilyl, diphenylsilyl, phenylsilyl, etc.

In the description, the boron group may include an alkyl boron group and an aryl boron group. Examples of the boron group may include a trimethylboron group, a triethylboron group, a t-butyldimethylboron group, a triphenylboron group, a diphenylboron group, a phenylboron group, etc.

In the description, the alkenyl may be linear or branched. The carbon number may be, e.g., 2 to 30, 2 to 20, or 2 to 10. Examples of the alkenyl may include vinyl, 1-butenyl, 1-pentenyl, 1,3-butadienyl aryl, styrenyl, stilbenyl, etc.

Hereinafter, an organic light emitting device according to an embodiment will be explained.

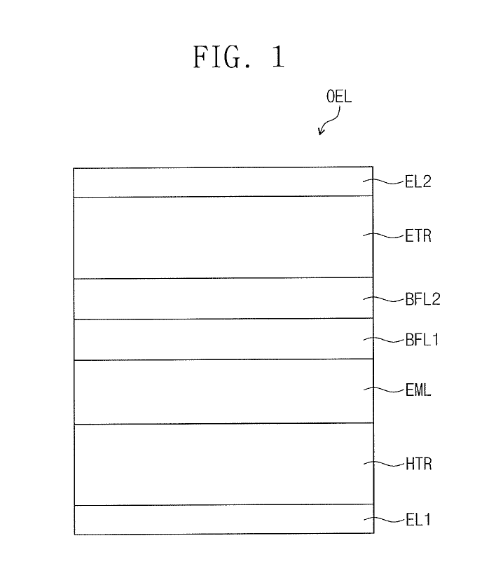

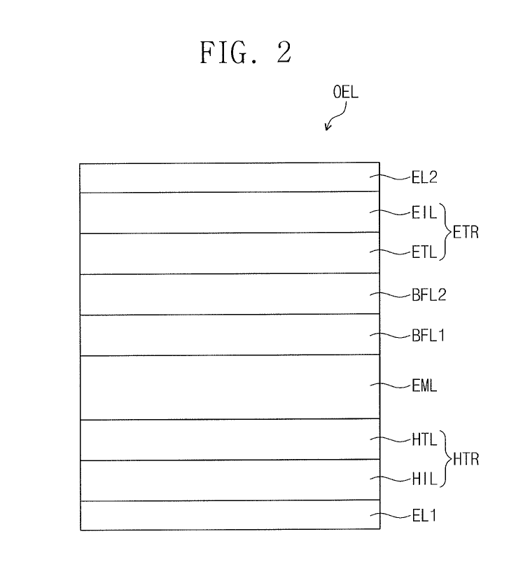

FIG. 1 illustrates a cross-sectional view schematically showing an organic light emitting device according to an embodiment. FIG. 2 illustrates a cross-sectional view schematically showing an organic light emitting device according to an embodiment.

Referring to FIGS. 1 and 2, an organic light emitting device OEL according to an embodiment may include, e.g., a first electrode EL1, a hole transport region HTR, an emission layer EML, a first buffer layer BFL1, a second buffer layer BFL2, an electron transport region ETR, and a second electrode EL2.

The first electrode EL1 may have conductivity. The first electrode EL1 may be a pixel electrode or an anode. The first electrode EL1 may be a transmissive electrode, a transflective electrode, or a reflective electrode. In the case that the first electrode EL1 is the transmissive electrode, the first electrode EL1 may be formed using a transparent metal oxide, e.g., indium tin oxide (ITO), indium zinc oxide (IZO), zinc oxide (ZnO), and indium tin zinc oxide (ITZO). In the case that the first electrode EL1 is the transflective electrode or the reflective electrode, the first electrode EL1 may include, e.g., Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In an implementation, the first electrode EL1 may include a plurality of layers including a reflective layer or a transflective layer formed using the above materials, and a transmissive layer formed using ITO, IZO, ZnO, or ITZO.

The hole transport region HTR may be provided on the first electrode EL1. The hole transport region HTR may include, e.g., at least one of a hole injection layer HIL, a hole transport layer HTL, a hole buffer layer, or an electron blocking layer.

In an implementation, the hole transport region HTR may have a single layer formed using a single material, a single layer formed using a plurality of different materials, or a multilayer structure including a plurality of layers formed using a plurality of different materials.

In an implementation, the hole transport region HTR may have the structure of a single layer such as a hole injection layer HIL, or a hole transport layer HTL, and may have a structure of a single layer formed using a hole injection material and a hole transport material. In an implementation, the hole transport region HTR may have a structure of a single layer formed using a plurality of different materials, or a structure laminated from the first electrode EL1 of hole injection layer HIL/hole transport layer HTL, hole injection layer HIL/hole transport layer HTL/hole buffer layer, hole injection layer HIL/hole buffer layer, hole transport layer HTL/hole buffer layer, or hole injection layer HIL/hole transport layer HTL/electron blocking layer.

The hole transport region HTR may be formed using various suitable methods such as a vacuum deposition method, a spin coating method, a cast method, a Langmuir-Blodgett (LB) method, an inkjet printing method, a laser printing method, and a laser induced thermal imaging (LITI) method.

In the case that the hole transport region HTR includes the hole injection layer HIL, the hole transport region HTR may include, e.g., a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), 2,3,6,7,10,11-hexacyano-1,4,5,8,9,12-hexaazatriphenylene (HAT-CN), polyetherketone including triphenylamine (TPAPEK), 4-isopropyl-4′-methyldiphenyliodonium tetrakis(pentafluorophenyl)borate, etc.

In the case that the hole transport region HTR includes the hole transport layer HTL, the hole transport region HTR may include, e.g., a carbazole derivative such as N-phenylcarbazole and polyvinyl carbazole, a fluorine- or fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(1-naphthyl)-N,N′-diphenylbenzidine (NPB), N,N′-diphenyl-N,N′-bis(1-naphthyl)-1,1′-biphenyl-4,4″-diamine (α-NPD), 4,4′-cyclohexylidene bis[N,N-bis(4-methylphenyl)benzeneamine] (TAPC), 4,4′-bis[N,N′-(3-tolyl)amino)-3,3′-dimethylbiphenyl (HMTPD), etc.

In an implementation, the thickness of the hole transport region HTR may be from about 100 Å to about 10,000 Å, e.g., from about 100 Å to about 1,000 Å. In the case that the hole transport region HTR includes both the hole injection layer HIL and the hole transport layer HTL, the thickness of the hole injection layer HIL may be from about 100 Å to about 10,000 Å, e.g., from about 100 Å to about 1,000 Å, and the thickness of the hole transport layer HTL may be from about 50 Å to about 2,000 Å, e.g., from about 100 Å to about 1,500 Å. In the case that the thicknesses of the hole transport region HTR, the hole injection layer HIL, and the hole transport layer HTL satisfy the above-described ranges, satisfactory hole transport properties may be obtained without substantial increase of a driving voltage.

In an implementation, the hole transport region HTR may further include a charge generating material other than the above-described materials to improve conductivity. The charge generating material may be dispersed in the hole transport region HTR uniformly or non-uniformly. The charge generating material may be, e.g., a p-dopant. The p-dopant may be one of a quinone derivative, a metal oxide, or a cyano group-containing compound. Examples of the p-dopant may include a quinone derivative such as tetracyanoquinodimethane (TCNQ), and 2,3,5,6-tetrafluoro-tetracyanoquinodimethane (F4-TCNQ), a metal oxide such as tungsten oxide, and molybdenum oxide.

In an implementation, the hole transport region HTR may further include one of a hole buffer layer and an electron blocking layer other than the hole injection layer HIL and the hole transport layer HTL. The hole buffer layer may help compensate an optical resonance distance according to the wavelength of light emitted from the emission layer EML and may help increase light emission efficiency. Materials included in the hole transport region HTR may be used as materials included in the hole buffer layer. The electron blocking layer is a layer that helps reduce and/or prevent electron injection from the electron transport region ETR to the hole transport region HTR.

The emission layer EML may be provided on the hole transport region HTR. The thickness of the emission layer EML may be from about 100 Å to about 500 Å. The emission layer EML may have a single layer formed using a single material, a single layer formed using a plurality of different materials, or a multilayer structure having a plurality of layers formed using a plurality of different materials.

The emission layer EML may emit one of red light, green light, blue light, white light, yellow light, or cyan light. The emission layer EML may include a phosphorescent material or a fluorescent material. In addition, the emission layer EML may include a host or a dopant.

The host may include a suitable host material, e.g., tris(8-hydroxyquinolino)aluminum (Alq3), 4,4′-bis(N-carbazolyl)-1,1′-biphenyl (CBP), poly(n-vinylcarbazole) (PVK), 9,10-di(naphthaline-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), etc.

The dopant may include, e.g., styryl derivatives (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, 1,4-bis(N,N-diphenylamino)pyrene), etc.

When the emission layer EML emits red light, the emission layer EML may include, e.g., tris(dibenzoylmethanato)phenanthroline europium (PBD:Eu(DBM)₃(Phen)), or a phosphorescent material including perylene. In the case that the emission layer EML emits red light, the dopant included in the emission layer EML may be selected from a metal complex or an organometallic complex such as bis(1-phenylisoquinoline)acetylacetonate iridium (PIQIr(acac)), bis(1-phenylquinoline)acetylacetonate iridium (PQIr(acac), tris(1-phenylquinoline)iridium (PQIr), and octaethylporphyrin platinum (PtOEP), rubrene and the derivatives thereof, or 4-dicyanomethylene-2-(p-dimethylaminostyryl)-6-methyl-4H-pyran (DCM) and derivatives thereof.

In the case that the emission layer EML emits green light, the emission layer EML may include a phosphorescent material including, e.g., tris(8-hydroxyquinolino)aluminum (Alq3). In the case that the emission layer EML emits green light, the dopant included in the emission layer EML may be selected from a metal complex or organometallic complex such as fac-tris(2-phenylpyridine)iridium (Ir(ppy)3), or a coumarin and the derivatives thereof.

In the case that the emission layer EML emits blue light, the emission layer EML may include a phosphorescent material including at least one selected from, e.g., spiro-DPVBi, spiro-6P, distyryl-benzene (DSB), distyryl-arylene (DSA), a polyfluorene (PFO)-based polymer, and a poly(p-phenylene vinylene) (PPV)-based polymer. In the case that the emission layer EML emits blue light, the dopant included in the emission layer EML may be selected from a metal complex or an organometallic complex such as (4,6-F2ppy)₂Irpic, or perylene and the derivatives thereof.

The first buffer layer BFL1 may be provided on the emission layer EML. The first buffer layer BFL1 may include, e.g., a first buffer compound represented by the following Formula 1 or Formula 2. In an implementation, the first buffer layer BFL1 may include the first buffer compound represented by the following Formula 1 or Formula 2, may help control the balance of holes and electrons in the emission layer EML, and may help compensate the color change of the organic light emitting device OEL at a low grey scale. Current may be flowing a lot at a high grey scale (e.g., greater than about 60 grey level), and the balance of holes and electrons and emission efficiency may not be influenced much. However, at a low grey scale (e.g., with about 0 grey level to about 60 grey level), a small difference of the balance between holes and electrons may have great influence on the emission efficiency. The organic light emitting device OEL according to an embodiment may include the first compound, and the injection of electrons even at a low grey scale may be facilitated. In addition, efficiency according to current may be similar to that at a high grey scale. In addition, in the case that the emission efficiency at a low grey scale becomes constant, the compensation on the color change may become possible.

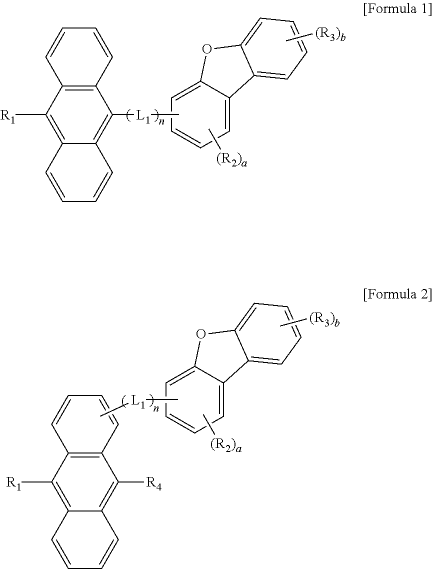

In Formulae 1 and 2, R₁, R₂, R₃ and R₄ may each independently be or include, e.g., a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms.

In an implementation, R₁ may be or may include, e.g., a substituted or unsubstituted phenyl group or substituted or unsubstituted naphthyl group. In an implementation, R₁ may be, e.g., a phenyl group substituted with phenanthrenyl, a phenyl group substituted with naphthyl, or a naphthyl group substituted with phenyl.

In the case that a is 2 or more (e.g., 2 or 3), a plurality of R₂s may be the same or different. In addition, at least one of the plurality of R₂s may be different. In the case that b is 2 or more (e.g., 2, 3, or 4), a plurality of R₃s may be the same or different. In addition, at least one of the plurality of R₃s may be different. R₄ may be or may include, e.g., a substituted or unsubstituted phenyl group.

In Formulae 1 and 2, a may be an integer from 0 to 3. In the case that a is 2 or more (e.g., 2 or 3), adjacent R₂s may be separate or may combine or be bound to form a ring. For example, adjacent R₂s may combine to form a ring such as the following A, B, or C. * represents a position making connection with L₁ or a phenanthrene group.

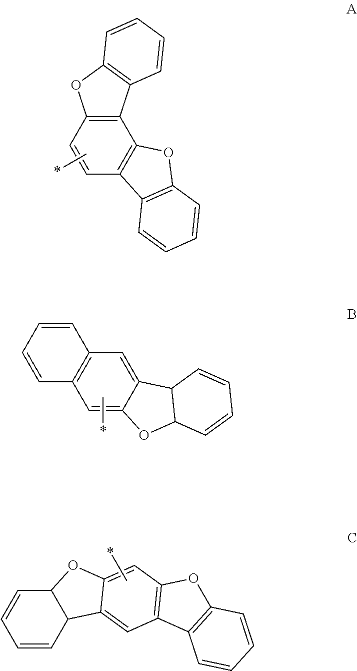

In Formulae 1 and 2, b may be an integer of 0 to 4. In the case that b is 2 or more (e.g., 2, 3, or 4), adjacent R₃s may be separate or may combine or be bound to form a ring. For example, adjacent R₃s may combine to form a ring such as the following A, B, or C. * represents a position making connection with L₁ or a phenanthrene group.

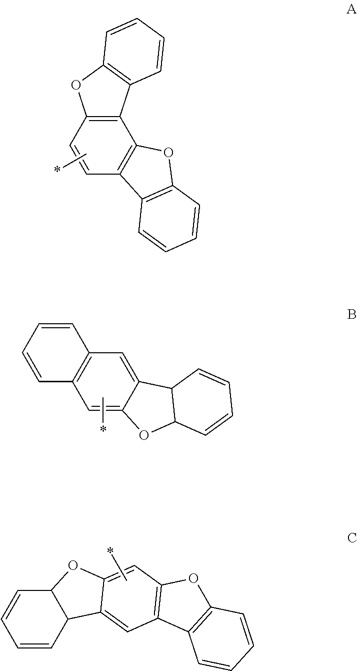

In Formulae 1 and 2, L₁ may be or may include, e.g., a direct linkage (e.g., a single bond), a substituted or unsubstituted arylene group having 6 to 30 ring carbon atoms, or a substituted or unsubstituted heteroarylene group having 4 to 30 ring carbon atoms. L₁ may be or may include, e.g., a substituted or unsubstituted m-phenylene group, a substituted or unsubstituted p-phenyl group, a substituted or unsubstituted fluorenylene group, or a substituted or unsubstituted dibenzofuranylene group. For example, the meta- of the m-phenylene group and the para- of the p-phenylene group refer to the bonding positions of the phenanthrene group and the dibenzofuran group to L₁.

In Formulae 1 and 2, n may be 0 or 1. In the case that n is 0, the phenanthrene group and the dibenzofuran group in Formula 1 may make a direct linkage.

In an implementation, the first buffer compound may include, e.g., one of the following Compounds 1 to 9.

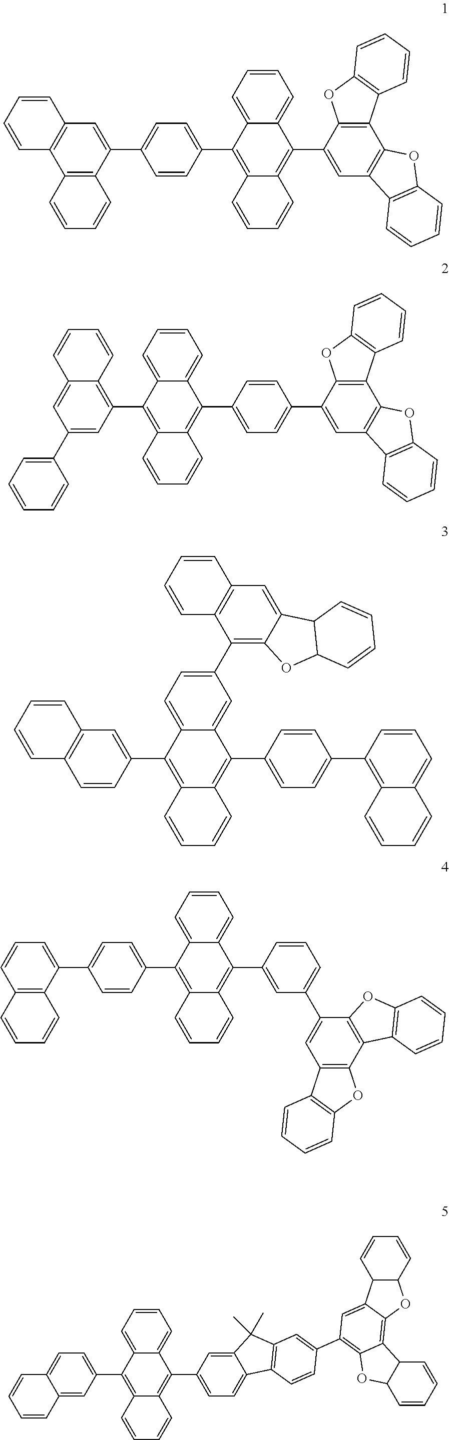 [SMILES: c1ccc2c(c1)cc(-c1ccc(-c3c4ccccc4c(-c4cc5c6ccccc6oc5c5c4oc4ccccc45)c4ccccc34)cc1)c1ccccc12 ; c1ccc(-c2cc(-c3c4ccccc4c(-c4ccc(-c5cc6c7ccccc7oc6c6c5oc5ccccc56)cc4)c4ccccc34)c3ccccc3c2)cc1 ; C1=CC2Oc3c(cc4ccccc4c3-c3ccc4c(-c5ccc6ccccc6c5)c5ccccc5c(-c5ccc(-c6cccc7ccccc67)cc5)c4c3)C2C=C1 ; c1cc(-c2c3ccccc3c(-c3ccc(-c4cccc5ccccc45)cc3)c3ccccc23)cc(-c2cc3c4ccccc4oc3c3c2oc2ccccc23)c1 ; CC1(C)c2cc(-c3cc4c(c5c3OC3C=CC=CC53)OC3C=CC=CC43)ccc2-c2ccc(-c3c4ccccc4c(-c4ccc5ccccc5c4)c4ccccc34)cc21]

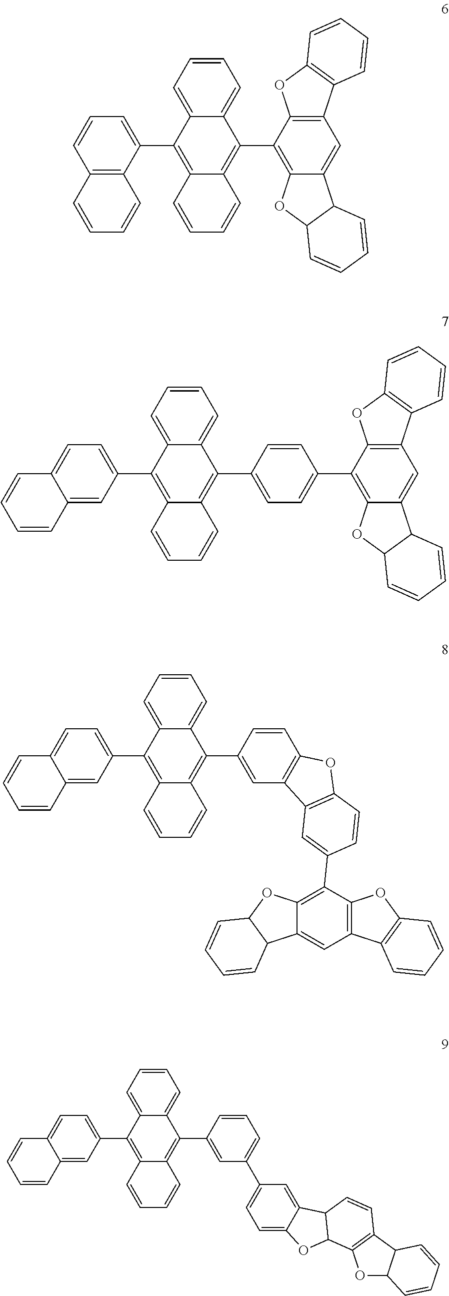 [SMILES: C1=CC2Oc3c(cc4c(oc5ccccc54)c3-c3c4ccccc4c(-c4cccc5ccccc45)c4ccccc34)C2C=C1 ; C1=CC2Oc3c(cc4c(oc5ccccc54)c3-c3ccc(-c4c5ccccc5c(-c5ccc6ccccc6c5)c5ccccc45)cc3)C2C=C1 ; C1=CC2Oc3c(cc4c(oc5ccccc54)c3-c3ccc4oc5ccc(-c6c7ccccc7c(-c7ccc8ccccc8c7)c7ccccc67)cc5c4c3)C2C=C1 ; C1=CC2OC3=C(C=CC4c5cc(-c6cccc(-c7c8ccccc8c(-c8ccc9ccccc9c8)c8ccccc78)c6)ccc5OC34)C2C=C1]

In an implementation, the thickness of the first buffer layer BFL1 may be, e.g., from about 10 Å to about 100 Å. Maintaining the thickness of the first buffer layer BFL1 at about 10 Å or greater may help ensure that holes passed through the emission layer EML are not transferred to the electron transport region ETR. Maintaining the thickness of the first buffer layer BFL1 at about 100 Å or less may help ensure that electrons are easily supplied from the electron transport region ETR to the emission layer EML.

The second buffer layer BFL2 may be provided on the first buffer layer BFL1. The second buffer layer BFL2 may include a second buffer compound represented by the following Formula 3. In an implementation, the second buffer layer BFL2 may include the second buffer compound represented by the following Formula 3, and the second buffer compound may have high electron mobility and may help improve the luminous efficacy of the organic light emitting device OEL. The second buffer compound may include a triazine group having high electron mobility. For example, the second buffer compound may help increase an amount of electrons reaching the emission layer EML, may help increase an amount of excitons, and may help improve the emission efficiency of the organic light emitting device OEL.

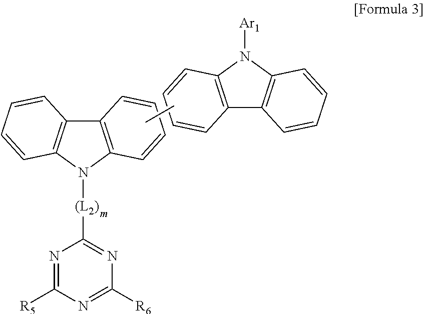

In Formula 3, R₅ and R₆ may each independently be or include, e.g., a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms. In an implementation, R₅ and R₆ may be or may include, e.g., a substituted or unsubstituted phenyl group, a substituted or unsubstituted biphenyl group, a substituted or unsubstituted naphthyl group, or a substituted or unsubstituted pyridine group.

In Formula 3, Ar₁ may be or may include, e.g., a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms. In an implementation, Ar₁ may be or may include, e.g., a substituted or unsubstituted phenyl group.

In Formula 3, L₂ may be or may include, e.g., a direct linkage (e.g., a single bond), a substituted or unsubstituted arylene group having 6 to 30 ring carbon atoms, or a substituted or unsubstituted heteroarylene group having 4 to 30 ring carbon atoms. In an implementation, L₂ may be or may include, e.g., a substituted or unsubstituted m-phenylene group or a substituted or unsubstituted p-phenylene group.

In Formula 3, m may be 0 or 1. In the case that m is 0, a carbazolylene group and a triazine group may make a direct linkage.

In an implementation, the second buffer compound may be represented by the following Formula 4.

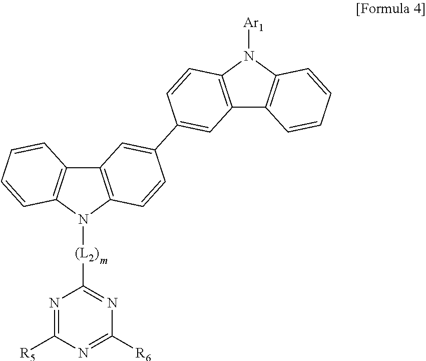

In Formula 4, Ar₁, L₂, R₅, R₆, and m are defined the same as those of Formula 3.

In an implementation, the second buffer compound may include, e.g., one of the following Compounds 1′ to 10′.

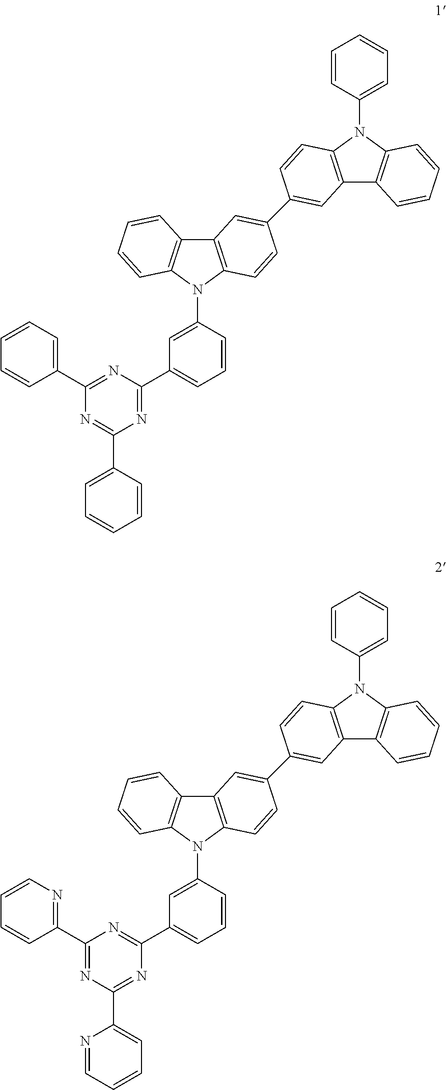 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-n2c3ccccc3c3cc(-c4ccc5c(c4)c4ccccc4n5-c4cccc(-c5nc(-c6ccccn6)nc(-c6ccccn6)n5)c4)ccc32)cc1]

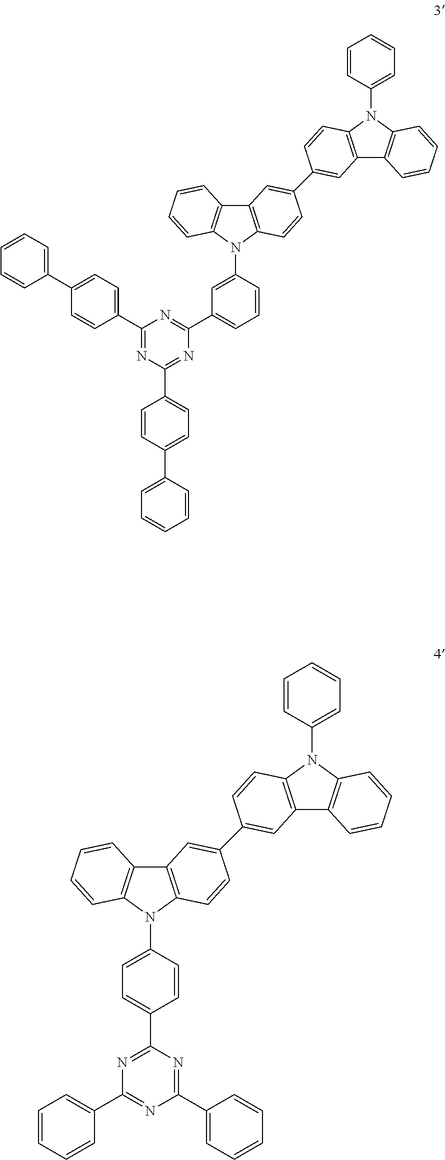 [SMILES: c1ccc(-c2ccc(-c3nc(-c4ccc(-c5ccccc5)cc4)nc(-c4cccc(-n5c6ccccc6c6cc(-c7ccc8c(c7)c7ccccc7n8-c7ccccc7)ccc65)c4)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

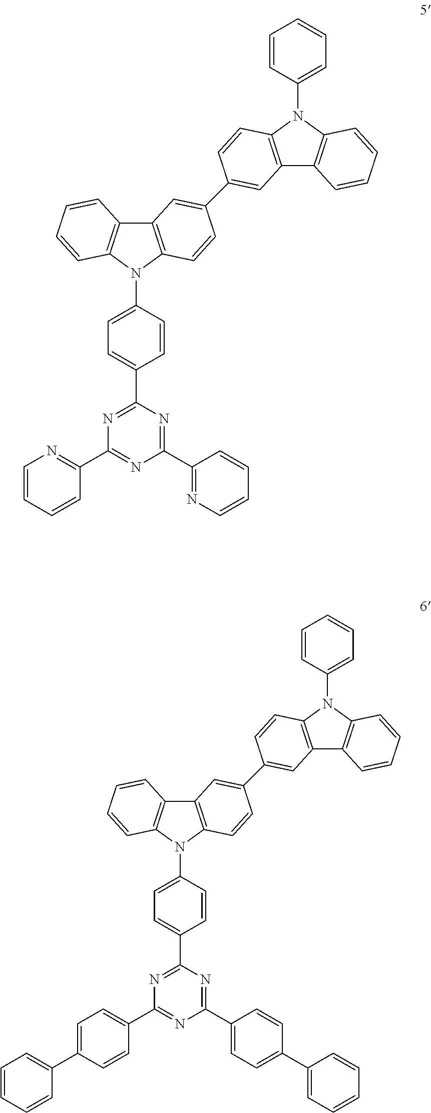 [SMILES: c1ccc(-n2c3ccccc3c3cc(-c4ccc5c(c4)c4ccccc4n5-c4ccc(-c5nc(-c6ccccn6)nc(-c6ccccn6)n5)cc4)ccc32)cc1 ; c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1]

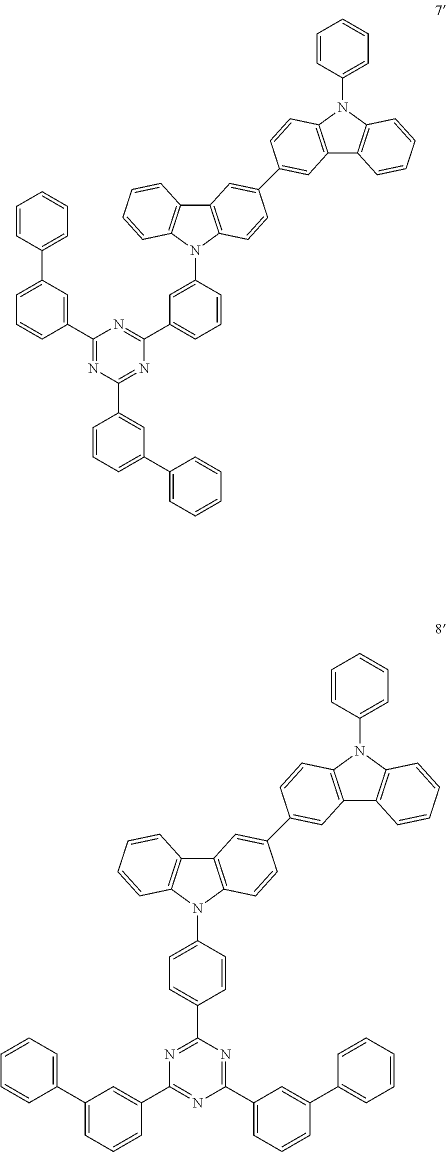 [SMILES: c1ccc(-c2cccc(-c3nc(-c4cccc(-c5ccccc5)c4)nc(-c4cccc(-n5c6ccccc6c6cc(-c7ccc8c(c7)c7ccccc7n8-c7ccccc7)ccc65)c4)n3)c2)cc1 ; c1ccc(-c2cccc(-c3nc(-c4ccc(-n5c6ccccc6c6cc(-c7ccc8c(c7)c7ccccc7n8-c7ccccc7)ccc65)cc4)nc(-c4cccc(-c5ccccc5)c4)n3)c2)cc1]

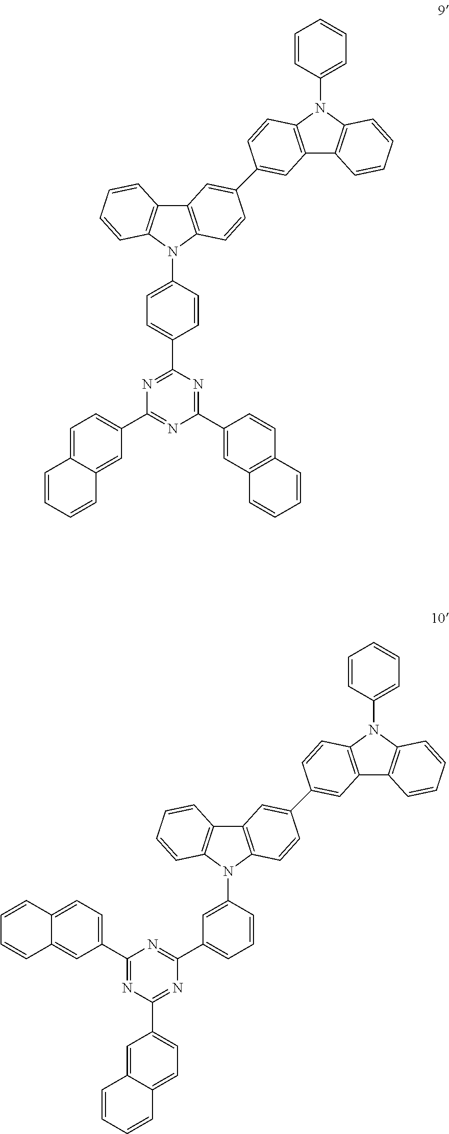 [SMILES: c1ccc(-n2c3ccccc3c3cc(-c4ccc5c(c4)c4ccccc4n5-c4ccc(-c5nc(-c6ccc7ccccc7c6)nc(-c6ccc7ccccc7c6)n5)cc4)ccc32)cc1 ; c1ccc(-n2c3ccccc3c3cc(-c4ccc5c(c4)c4ccccc4n5-c4cccc(-c5nc(-c6ccc7ccccc7c6)nc(-c6ccc7ccccc7c6)n5)c4)ccc32)cc1]

In an implementation, the thickness of the second buffer layer BFL2 may be the same as or different from the thickness of the first buffer layer BFL1. In an implementation, the thickness of the second buffer layer BFL2 may be, e.g., from about 10 Å to about 100 Å. Maintaining the thickness of the second buffer layer BFL2 at about 10 Å or greater may help ensure that holes passed through the emission layer EML are not transferred to the electron transport region ETR. Maintaining the thickness of the second buffer layer BFL2 at about 100 Å or less may help ensure that the electrons are easily supplied from the electron transport region ETR to the emission layer EML.

The electron transport region ETR may be provided on the second buffer layer BFL2. In an implementation, the electron transport region ETR may include at least one of an electron blocking layer, an electron transport layer ETL or an electron injection layer EIL.

In an implementation, the electron transport region ETR may have a single layer formed using a single material, a single layer formed using a plurality of different materials, or a multilayer structure having a plurality of layers formed using a plurality of different materials.

In an implementation, the electron transport region ETR may have a single layer structure of the electron injection layer EIL or the electron transport layer ETL, or a single layer structure formed using an electron injection material and an electron transport material. In an implementation, the electron transport region ETR may have a single layer structure having a plurality of different materials, or a structure laminated from the first electrode EL1 of electron transport layer ETL/electron injection layer EIL, or hole blocking layer/electron transport layer ETL/electron injection layer EIL. In an implementation, the thickness of the electron transport region ETR may be, e.g., from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and a laser induced thermal imaging (LITI) method.

In the case that the electron transport region ETR includes the electron transport layer ETL, the electron transport region ETR may include, e.g., tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq2), 9,10-di(naphthalene-2-yl)anthracene (ADN), or a mixture thereof. In an implementation, the thickness of the electron transport layer ETL may be from about 100 Å to about 1,000 Å, e.g., about 150 Å to about 500 Å. If the thickness of the electron transport layer ETL satisfies the above-described range, satisfactory electron transport property may be obtained without substantial increase of a driving voltage.

When the electron transport region ETR includes the electron injection layer EIL, the electron transport region ETR may include, e.g., LiF, lithium quinolate (LiQ), Li₂O, BaO, NaCl, CsF, a metal in lanthanides such as Yb, or a metal halide such as RbCl and RbI. The electron injection layer EIL also may be formed using a mixture material of an electron transport material and an insulating organo metal salt. The organo metal salt may be a material having an energy band gap of about 4 eV or more. In an implementation, the organo metal salt may include, e.g., a metal acetate, a metal benzoate, a metal acetoacetate, a metal acetylacetonate, or a metal stearate. In an implementation, the thickness of the electron injection layer EIL may be from about 1 Å to about 100 Å, e.g., about 3 Å to about 90 Å. In the case that the thickness of the electron injection layer EIL satisfies the above described range, satisfactory electron injection property may be obtained without inducing the substantial increase of a driving voltage.

The electron transport region ETR may include a hole blocking layer, as described above. In an implementation, the hole blocking layer may include, e.g., 2,9-dimethyl-4,7-diphenyl-1,10-phenanthroline (BCP), or 4,7-diphenyl-1,10-phenanthroline (Bphen).

The second electrode EL2 may be provided on the electron transport region ETR. The second electrode EL2 may be a common electrode or a cathode. The second electrode EL2 may be a transmissive electrode, a transflective electrode, or a reflective electrode. In the case that the second electrode EL2 is the transmissive electrode, the second electrode EL2 may include, e.g., a transparent metal oxide, for example, ITO, IZO, ZnO, ITZO, etc.

In the case that the second electrode EL2 is the transflective electrode or the reflective electrode, the second electrode EL2 may include, e.g., Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The second electrode EL2 may have a multilayered structure including a reflective layer or a transflective layer formed using the above-described materials and a transparent conductive layer formed using ITO, IZO, ZnO, ITZO, etc.

In an implementation, the second electrode EL2 may be connected with an auxiliary electrode. In the case that the second electrode EL2 is connected with the auxiliary electrode, the resistance of the second electrode EL2 may decrease.

In the organic light emitting device OEL, according to the application of a voltage to each of the first electrode EL1 and second electrode EL2, holes injected from the first electrode EL1 may transfer via the hole transport region HTR to the emission layer EML, and electrons injected from the second electrode EL2 may transfer via the electron transport region ETR to the emission layer EML. The electrons and the holes are recombined in the emission layer EML to generate excitons, and the excitons may emit light via transition from an excited state to a ground state.

In the case that the organic light emitting device OEL is a top emission type, the first electrode EL1 may be a reflective electrode, and the second electrode EL2 may be a transmissive electrode or a transflective electrode. In the case that the organic light emitting device OEL is a bottom emission type, the first electrode EL1 may be a transmissive electrode or a transflective electrode, and the second electrode EL2 may be a reflective electrode.

The organic light emitting device according to an embodiment may include, e.g., a first buffer layer including a first buffer compound represented by Formula 1 or Formula 2, thereby improving color change at a low grey scale. The organic light emitting device according to an embodiment may include, e.g., a second buffer layer including a second buffer compound represented by Formula 3, thereby improving emission efficiency. The low grey scale may mean 0 to 60 grey levels.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Example 1

On a glass substrate, an anode was formed using ITO and Ag to a thickness of about 80 Å. The, a hole injection layer was formed using 2-TNATA to a thickness of about 1,500 Å, a hole transport layer was formed using N,N′-bis(3-methylphenyl)-N,N′-diphenyl-[1,1-biphenyl]-4,4′-diamine (TPD) to a thickness of about 450 Å, an emission layer was formed using 9,10-di(2-naphthyl)anthracene (ADN) doped with 2,5,8,11-tetra-t-butylperylene (TBP) to a thickness of about 220 Å, a first buffer layer was formed using the following Compound 3 to a thickness of about 50 Å, a second buffer layer was formed using the following Compound 1′ to a thickness of about 50 Å, an electron transport layer was formed using Alq3 to a thickness of about 310 Å, an electron injection layer was formed using LiF to a thickness of about 15 Å, and a cathode was formed using MgAg (Mg:Ag=9:1) to a thickness of about 130 Å.

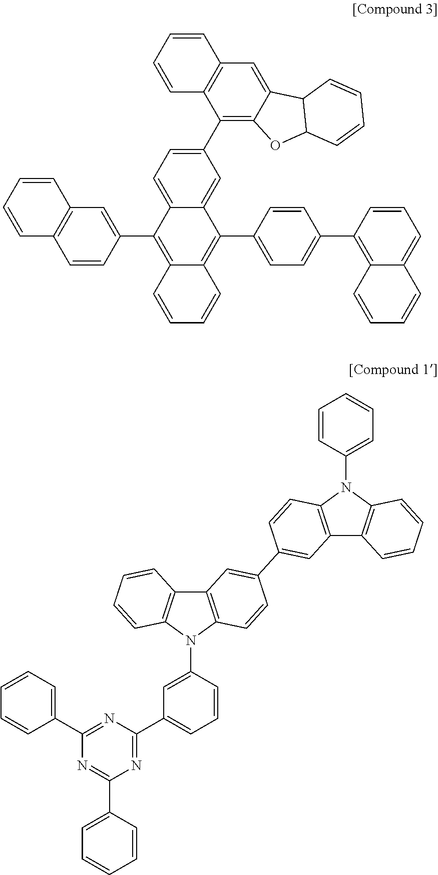 [SMILES: C1=CC2Oc3c(cc4ccccc4c3-c3ccc4c(-c5ccc6ccccc6c5)c5ccccc5c(-c5ccc(-c6cccc7ccccc67)cc5)c4c3)C2C=C1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

### Comparative Example 1

The same procedure described in Example 1 was conducted except for not forming the first buffer layer.

### Experimental Results

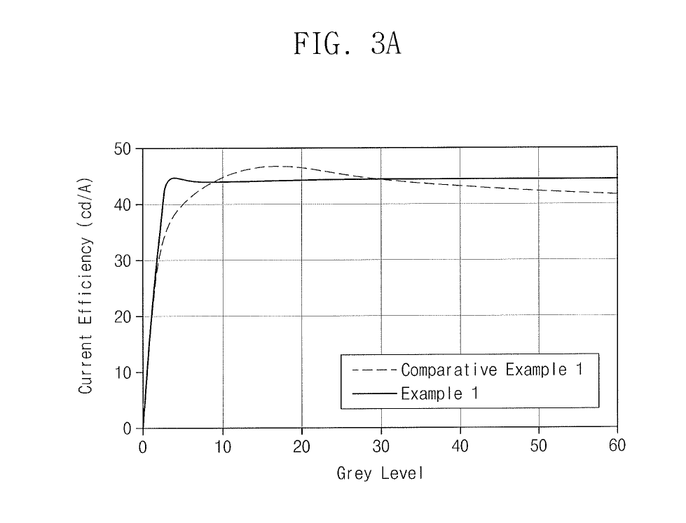

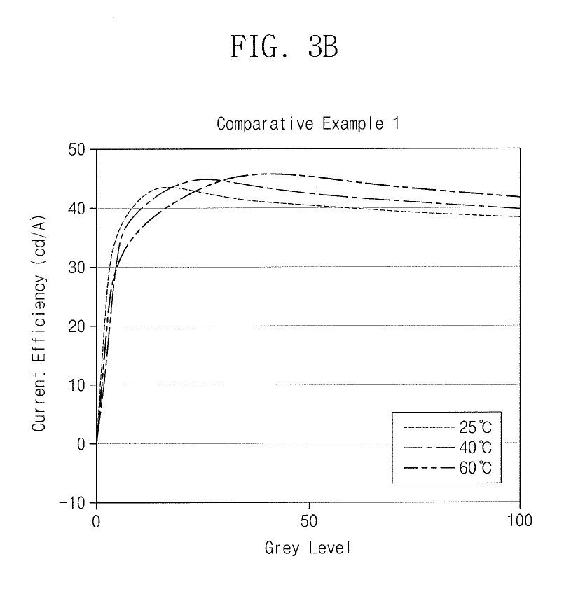

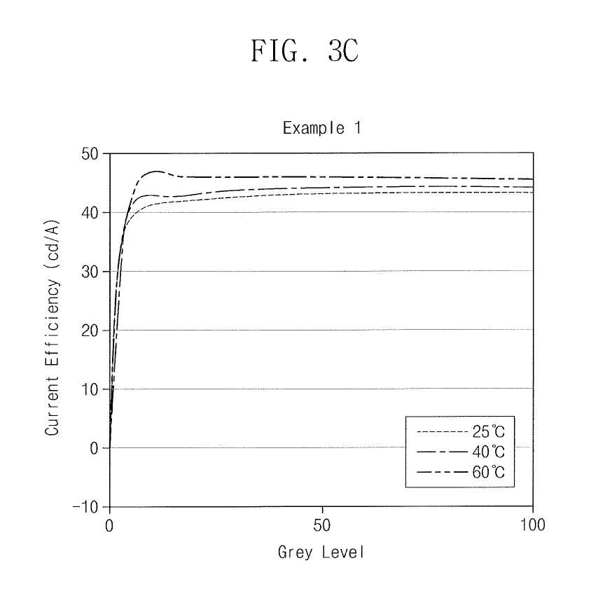

The luminous efficacy of Example 1 and Comparative Example 1 was measured. The luminous efficacy was obtained by measuring the luminous efficacy of an organic light emitting device during driving under the conditions of a current density of about 10 mA/cm². Referring to FIGS. 3A and 3B, it may be seen that the luminous efficacy of Comparative Example 1 was deteriorated at a low grey scale with the grey level of 0 to 60. However, referring to FIGS. 3A and 3C, it may be seen that the luminous efficacy of Example 1 was improved at a low grey scale with the grey level of 0 to 80 when compared to that of Comparative Example 1.

In addition, referring to FIGS. 3B and 3C, it may be seen that the luminous efficacy at a low grey scale was maintained relatively constantly for Example 1, however the luminous efficacy at a low grey scale was not maintained constantly for Comparative Example 1.

By way of summation and review, in the application of an organic light emitting device to a display device, it may be desirable for the driving voltage to be decreased, and the emission efficiency and the life of the organic light emitting device may be increased.

In order to improve the efficiency of the organic light emitting device, a buffer layer may be included used between an emission layer and an electron transport region. The buffer layer may raise issues having to do with color change at a low grey scale.

In the organic light emitting device according to an embodiment, emission efficiency may be improved, and color change at a low grey scale may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting device, comprising:
a first electrode;
a hole transport region on the first electrode;
an emission layer on the hole transport region;
a first buffer layer on the emission layer;
a second buffer layer on the first buffer layer;
an electron transport region on the second buffer layer; and
a second electrode on the electron transport region,
wherein the first buffer layer includes a first buffer compound represented by the following Formula 1 or Formula 2, and the second buffer layer includes a second buffer compound represented by the following Formula 3: 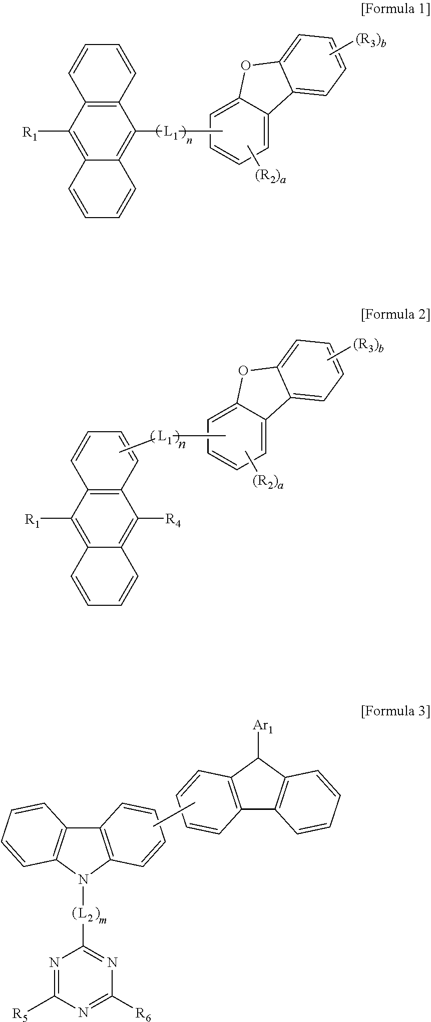
wherein, in Formulae 1 to 3,
R₁, R₂, R₃, R₄, R₅ and R₆ are each independently a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms,
R₁, R₂, R₃, R₄, R₅ and R₆ are separate or adjacent ones thereof combine to form a ring,
Ar₁ is a substituted or unsubstituted alkyl group having 1 to 20 carbon atoms, a substituted or unsubstituted aryl group having 6 to 30 ring carbon atoms, or a substituted or unsubstituted heteroaryl group having 5 to 30 ring carbon atoms,
L₁ and L₂ are each independently a direct linkage, a substituted or unsubstituted arylene group having 6 to 30 ring carbon atoms, or a substituted or unsubstituted heteroarylene group having 4 to 30 ring carbon atoms,
a is an integer of 0 to 3,
b is an integer of 0 to 4, and
n and m are each independently 0 or 1.

2. The organic light emitting device as claimed in claim 1, wherein, in Formulae 1 and 2, R₁ is a substituted or unsubstituted phenyl group or a substituted or unsubstituted naphthyl group.

3. The organic light emitting device as claimed in claim 1, wherein, in Formulae 1 and 2, L₁ is a substituted or unsubstituted m-phenylene group, substituted or unsubstituted p-phenylene group, a substituted or unsubstituted fluorenylene group, or a substituted or unsubstituted dibenzofuranyl group.

4. The organic light emitting device as claimed in claim 1, wherein, in Formulae 1 and 2, a is 2 or 3 and adjacent ones of R₂ combine to form a ring.

5. The organic light emitting device as claimed in claim 1, wherein, in Formulae 1 and 2, b is 2, 3, or 4, and adjacent one of R₃ combine to form a ring.

6. The organic light emitting device as claimed in claim 1, wherein, in Formula 2, R₄ is a substituted or unsubstituted phenyl group.

7. The organic light emitting device as claimed in claim 1, wherein the first buffer compound includes one of the following Compounds 1 to 9:

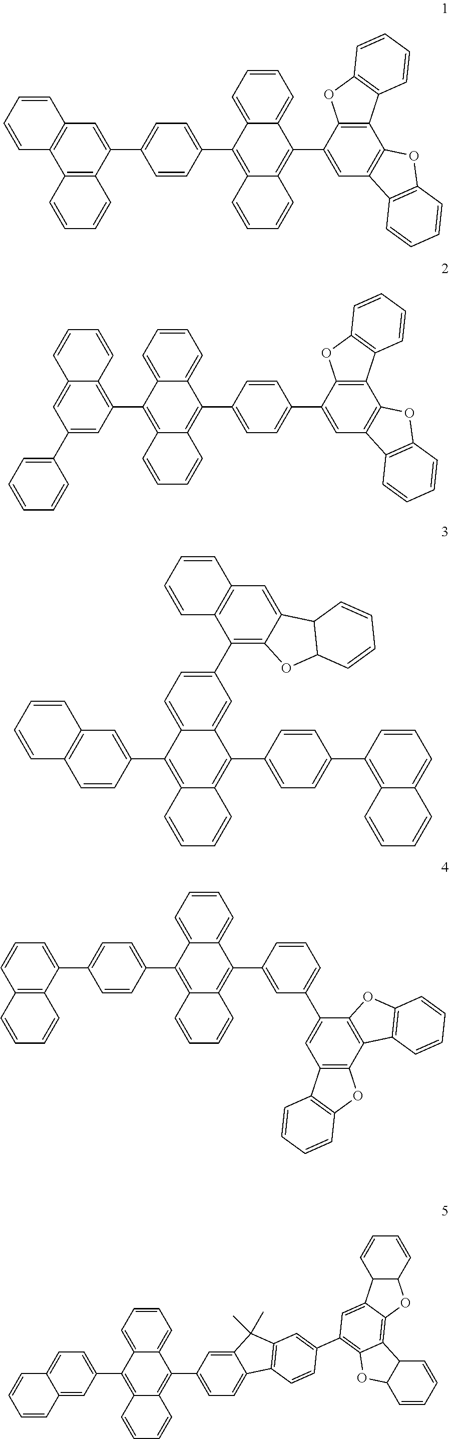 [SMILES: c1ccc2c(c1)cc(-c1ccc(-c3c4ccccc4c(-c4cc5c6ccccc6oc5c5c4oc4ccccc45)c4ccccc34)cc1)c1ccccc12 ; c1ccc(-c2cc(-c3c4ccccc4c(-c4ccc(-c5cc6c7ccccc7oc6c6c5oc5ccccc56)cc4)c4ccccc34)c3ccccc3c2)cc1 ; C1=CC2Oc3c(cc4ccccc4c3-c3ccc4c(-c5ccc6ccccc6c5)c5ccccc5c(-c5ccc(-c6cccc7ccccc67)cc5)c4c3)C2C=C1 ; c1cc(-c2c3ccccc3c(-c3ccc(-c4cccc5ccccc45)cc3)c3ccccc23)cc(-c2cc3c4ccccc4oc3c3c2oc2ccccc23)c1 ; CC1(C)c2cc(-c3cc4c(c5c3OC3C=CC=CC53)OC3C=CC=CC43)ccc2-c2ccc(-c3c4ccccc4c(-c4ccc5ccccc5c4)c4ccccc34)cc21]

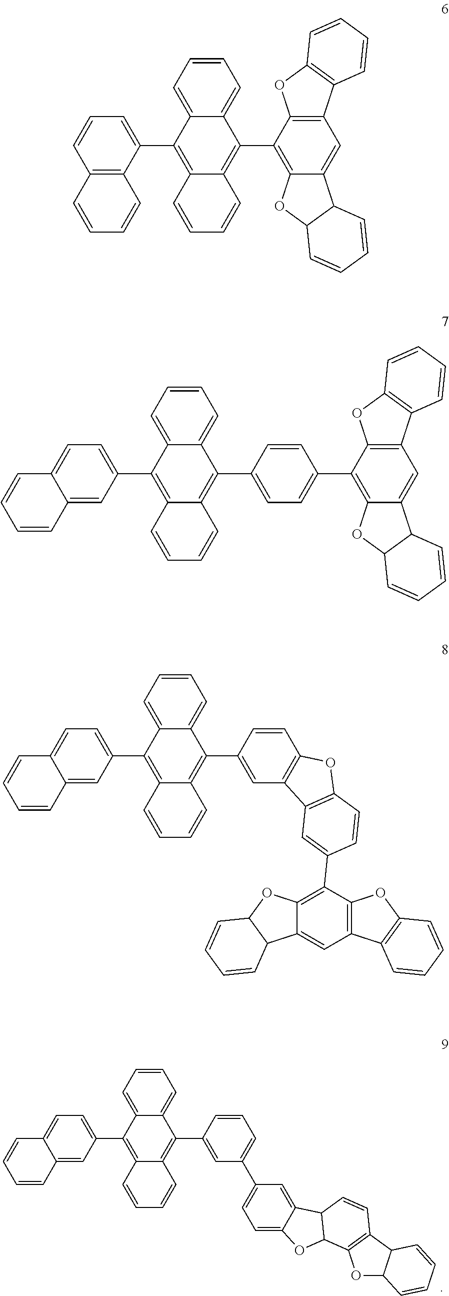 [SMILES: C1=CC2Oc3c(cc4c(oc5ccccc54)c3-c3c4ccccc4c(-c4cccc5ccccc45)c4ccccc34)C2C=C1 ; C1=CC2Oc3c(cc4c(oc5ccccc54)c3-c3ccc(-c4c5ccccc5c(-c5ccc6ccccc6c5)c5ccccc45)cc3)C2C=C1 ; C1=CC2Oc3c(cc4c(oc5ccccc54)c3-c3ccc4oc5ccc(-c6c7ccccc7c(-c7ccc8ccccc8c7)c7ccccc67)cc5c4c3)C2C=C1 ; C1=CC2OC3=C(C=CC4c5cc(-c6cccc(-c7c8ccccc8c(-c8ccc9ccccc9c8)c8ccccc78)c6)ccc5OC34)C2C=C1]

8. The organic light emitting device as claimed in claim 1, wherein the second buffer compound is represented by the following Formula 4: 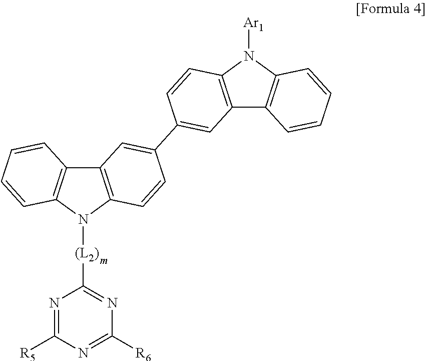
wherein, in Formula 4, Ar₁, L₂, m, R₅ and R₆ are defined the same as those of Formula 3.

9. The organic light emitting device as claimed in claim 1, wherein, in Formula 3, Ar₁ is a substituted or unsubstituted phenyl group.

10. The organic light emitting device as claimed in claim 1, wherein, in Formula 3, L₂ is a substituted or unsubstituted m-phenylene group or a substituted or unsubstituted p-phenylene group.

11. The organic light emitting device as claimed in claim 1, wherein, in Formula 3, R₅ and R₆ are each independently selected from a substituted or unsubstituted phenyl group, a substituted or unsubstituted biphenyl group, a substituted or unsubstituted naphthyl group, or a substituted or unsubstituted pyridine group.

12. The organic light emitting device as claimed in claim 1, wherein the second buffer compound includes one of the following Compounds 1′ to 10′:

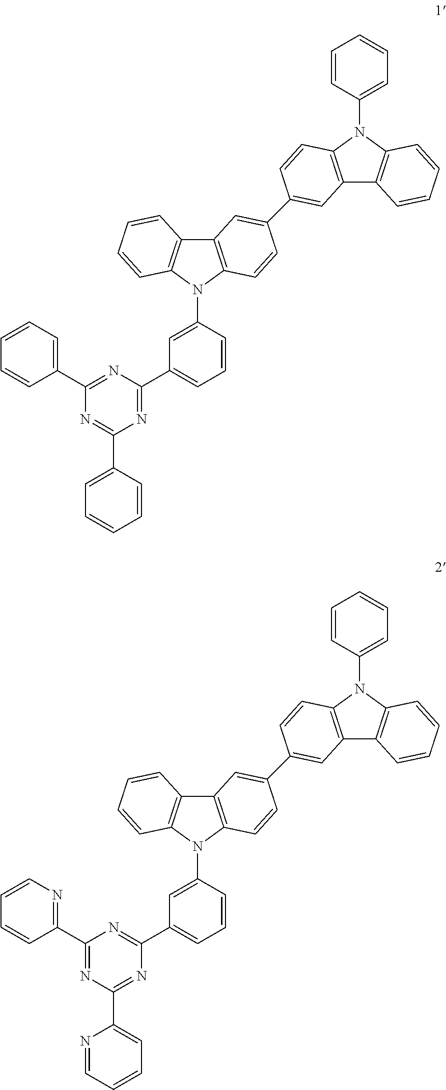 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-n2c3ccccc3c3cc(-c4ccc5c(c4)c4ccccc4n5-c4cccc(-c5nc(-c6ccccn6)nc(-c6ccccn6)n5)c4)ccc32)cc1]

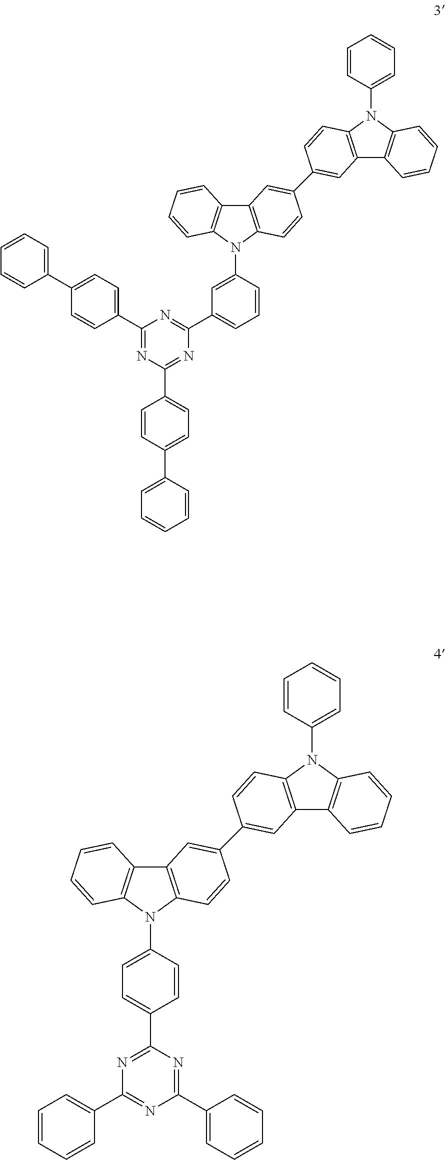 [SMILES: c1ccc(-c2ccc(-c3nc(-c4ccc(-c5ccccc5)cc4)nc(-c4cccc(-n5c6ccccc6c6cc(-c7ccc8c(c7)c7ccccc7n8-c7ccccc7)ccc65)c4)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

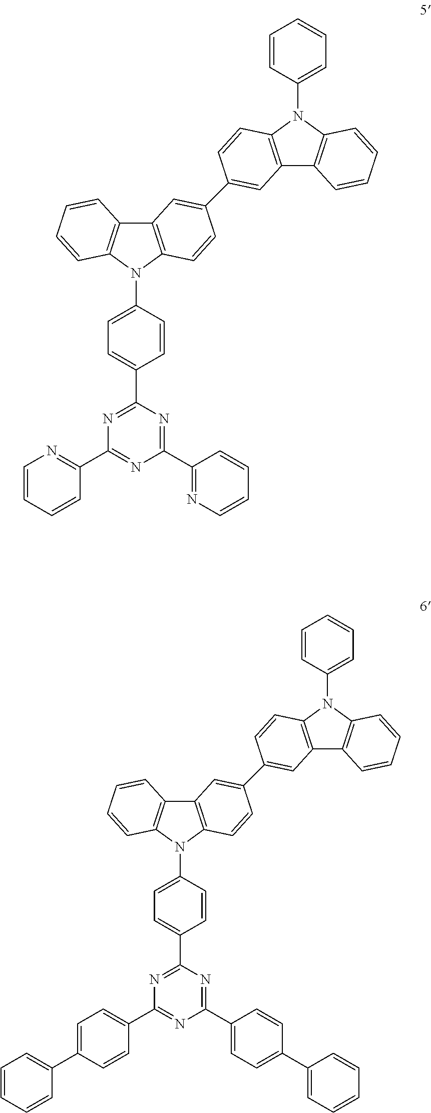 [SMILES: c1ccc(-n2c3ccccc3c3cc(-c4ccc5c(c4)c4ccccc4n5-c4ccc(-c5nc(-c6ccccn6)nc(-c6ccccn6)n5)cc4)ccc32)cc1 ; c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1]

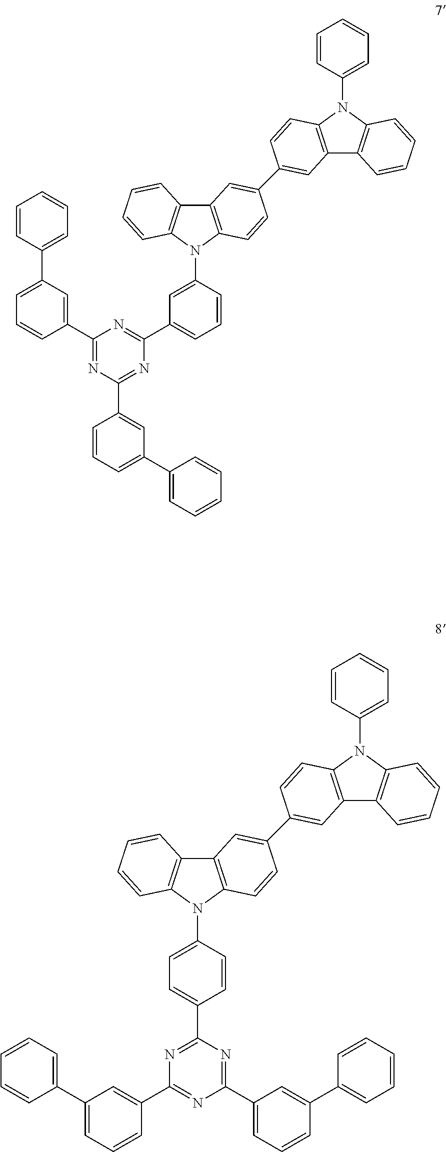 [SMILES: c1ccc(-c2cccc(-c3nc(-c4cccc(-c5ccccc5)c4)nc(-c4cccc(-n5c6ccccc6c6cc(-c7ccc8c(c7)c7ccccc7n8-c7ccccc7)ccc65)c4)n3)c2)cc1 ; c1ccc(-c2cccc(-c3nc(-c4ccc(-n5c6ccccc6c6cc(-c7ccc8c(c7)c7ccccc7n8-c7ccccc7)ccc65)cc4)nc(-c4cccc(-c5ccccc5)c4)n3)c2)cc1]

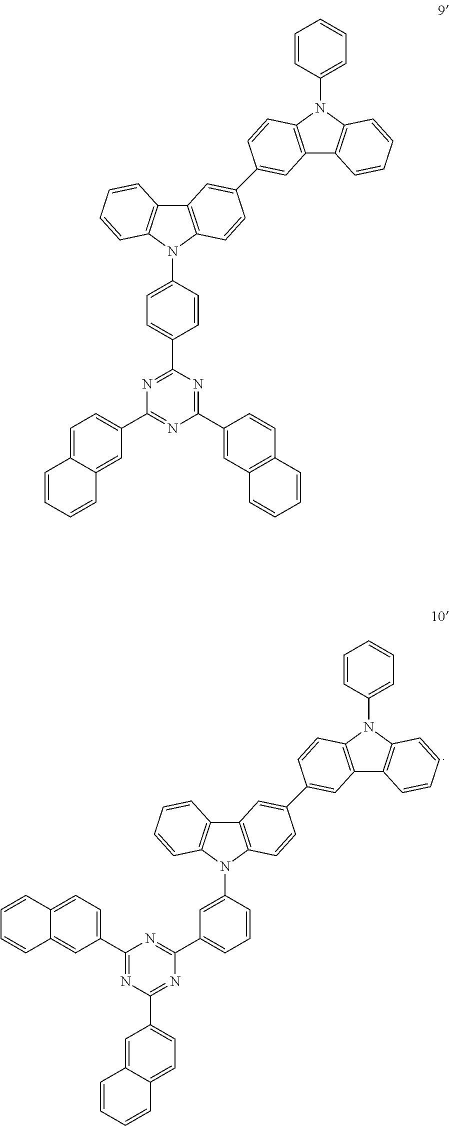 [SMILES: c1ccc(-n2c3ccccc3c3cc(-c4ccc5c(c4)c4ccccc4n5-c4ccc(-c5nc(-c6ccc7ccccc7c6)nc(-c6ccc7ccccc7c6)n5)cc4)ccc32)cc1 ; c1ccc(-n2c3ccccc3c3cc(-c4ccc5c(c4)c4ccccc4n5-c4cccc(-c5nc(-c6ccc7ccccc7c6)nc(-c6ccc7ccccc7c6)n5)c4)ccc32)cc1]

13. The organic light emitting device as claimed in claim 1, wherein the hole transport region includes:
a hole injection layer; and
a hole transport layer on the hole injection layer.

14. The organic light emitting device as claimed in claim 1, wherein the electron transport region includes:
an electron transport layer; and
an electron injection layer on the electron transport layer.
